(19) United States
(12) Patent Application Publication
(10) Pub. No.: US 2008/0098050 A1
(43) Pub. Date: Apr. 24, 2008

(54) Defect Management for Storage Media

(75) Inventor: Josephus Joannes Mathijs Maria Geelen, Susteren (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/571,459

(22) PCT Filed: Jun. 24, 2005
(86) PCT No.: PCT/IB05/52106

§ 371 Date: Dec. 29, 2006

Related U.S. Application Data
(60) Provisional application No. 60/584,195, filed on Jun. 30, 2004.

(51) Int. Cl. G11C 29/04; G06F 17/30; G06F 11/00; G06F 12/00

(52) U.S. Cl. 707/205; 714/723; 707/E17.005; 714/E11.02

(57) ABSTRACT

A write recovery strategy for optical recorders, whereby one good or certified disc extent is searched for once the disc is first loaded. The certified disc extent is reserved and is used as space to rewrite data for which initial writing attempts were unsuccessful. The reserved areas is used for write recovery at times of at the start, real-time AV data will not be lost and recording performance is improved. A series of lists are maintained including a reserved list of extents that are certified as being free of defects and lists for free and written areas of the disc. The defect list used is updated by the defect management scheme so that it is always up-to-date.

The present invention relates to defect management within storage media and more particularly, to defect management areas in optical discs using lists.

Recent optical disk standards have evolved that provide storage for high-density data. Among the standards are those that provide for writable optical discs. A problem that exists in writing high-density data is the potential for errors in the writing process. A substantial potential source of errors is due to defects within the discs. One recent standard, the Blu-ray Disc (BD) standard, describes an optical disc system for recording and playback of audiovisual (AV) streams. The Blu-ray standard provides for the handling of defects by implementation of a defect management scheme that employees a defect list containing list of the bad data blocks and data blocks that are potentially bad. The Blu-ray standard has defined additional indicators to show if a sector is replaced or defective. These indicators show if a sector is not error-free. The intention of implementing a defect list within the Blu-ray standard is allow for placement of defects that are discovered during writing or reading into the defect list.

Typically, during the recording of AV data, the defect list is consulted to determine the physical addresses where AV data should not be located. A problem that exists using this method is that the defect list will generally be outdated. The reasons that the defect list will be outdated, can be related to defects that occur due to the natural aging process the disc, contamination on disc from the ambient environment, damage that occurs is due to scratching of the disc, and other reasons that occur during the normal lifetime of the disc such as sector that can be worn-out because of to many overwrites, handling of the Disc by end-user can introduce Finger prints, scratches etc.

The detection of additionally occurring bad blocks on the disc and the updating of the defect list to include these additionally occurring bad blocks, operates with an efficiency that is implementation dependent. The problem is not only to find additional defects but also to validate existing defects. Therefore, defects due fingerprints can be outdate because the fingerprint is wiped-out. Defects can only reliably be detected by the writing and/or Reading of sectors. Therefore, all certification implementations have the common problem that it takes too much time to certify the disc when a recording needs to be started directly after inserting the Disc into the recorder/player.

The defect list is fully up to date after a full disc certification. However a full disc certification is very time-consuming which makes full disc certification very impractical during normal use the disc. Real-time recording concerns make full disc certification during recording virtually impossible.

As a result of the defect list not being up to date, it is not uncommon for a writing process to fail. Additionally, attempts at recovering from a failed writing process by re- writing the same data at another location on the disc can fail because the system erroneously believes that the other location selected for the re-writing attempt is defect free, and thus will fail if the other location is also defective. This creates a situation that can result in numerous attempts at re-writing and can easily result in the loss of data. During real-time recording the loss of data is a significant possibility.

Writing recovery is typically accomplished by writing into a different area of the disc. Worst case situations can occur where there are many bad data blocks on the disc, and attempts at rewriting data into a different area of the disc could potentially take several retries (the re-writes can also fail due to bad blocks). Additionally, the chance that attempts of re-writing will fail increases as free disc space decreases. Also, the additional attempts at rewriting during real-time data situations enormously increase the use of the memory (buffer), this is especially true in situation having high bitrates (such as HDTV) that are higher than or equal to 20 Mbit/sec., a temporary Buffer holds the data to be written causing day to resulting bottleneck in the buffer budget.

Accordingly, there is a need within the art for a system and method that can effectively re-write data without requiring undue, multiple attempts at rewriting that can result in the loss of data during recording operations. This need is especially significant in real time recordings where the recovery must be ‘time deterministic’.

Additionally, there remains a need within the art for a system and method that will take the necessary precautions that enable writing error recovery.

It is an object of the invention to address the aforementioned needs within the prior art and to provide a guaranteed rewrite action, wherein, only one attempt at rewriting data is required once a write error is detected.

These objects are provided for by player/recorder for storage media having a content buffer that is configured to receive data for the player/recorder and a control unit that designates areas within the storage media to place data received by the content buffer.

The control unit implements a series of lists a free area list that designates areas within the storage media that are not used, a defect list detailing areas of the storage media that are defective and a reserved area list designating areas of the storage media that are certified as being free of defects.

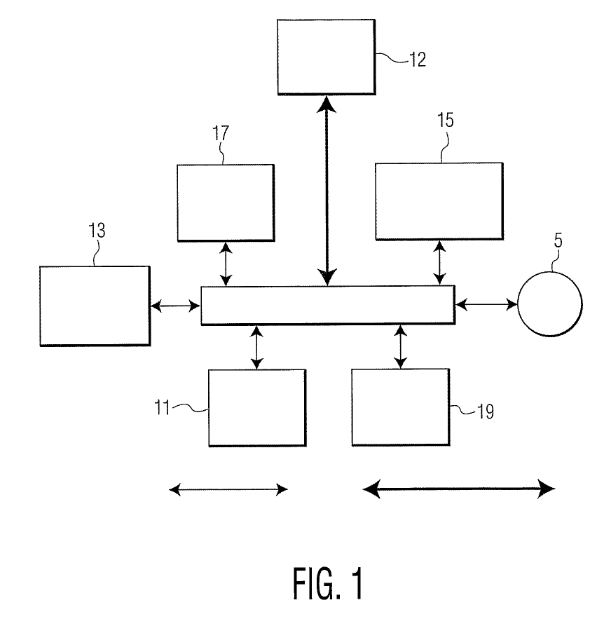

FIG. 1 is a block diagram illustrating the data structures that are envisioned by the invention;

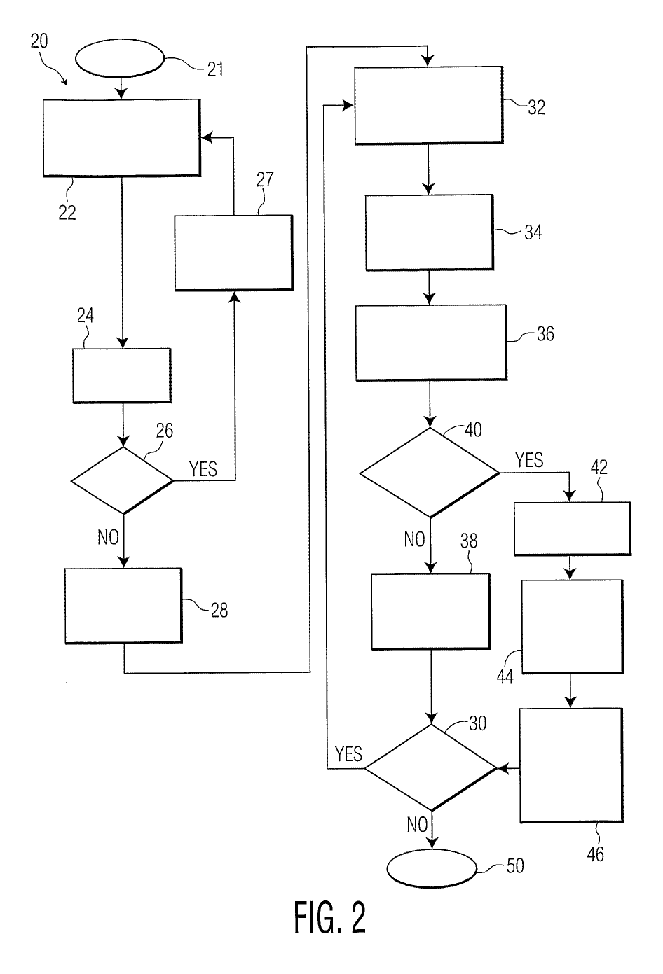

FIG. 2 is a flow chart for the algorithm of the preferred embodiment of the invention.

### BACK GROUND INFORMATION

The preferred embodiment of the Invention will be described as pertaining to Blu- ray discs, however, persons skilled within the art will understand that the features the invention are applicable to all optical discs and storage media of various types. Accordingly while the preferred embodiment discusses implementation on Blu-ray discs it should be understood that the particular nomenclature that is used in reference to Blu-ray discs will be generally equivalent to structures having a different nomenclature within other types storage media.

Within Blu-ray discs, AV real-time data is recorded on consecutive areas on disc also called Extents. For BD, An AV recording is presented as File. (AV) File data is writing in Extents, and Extents (of the same AV File) can be randomly allocated. So only AV data is written in Extents.

An Extent has a minimum size and can be randomly located on disc. An Extent, as used herein, is a consecutive area that is a set of logical sectors to which consecutive logical sector numbers are assigned. A piece of consecutive file data is allocated in the Extent. Extents therefore refer to areas that are logically consecutive. Detailed information can be found in the Blu-ray standard 1.0 part 2 starting chapter “Allocation rule for BDAV Domain”.

The premier concept envisioned by the present invention is that upon insertion of a disc into a player/recorder and before any attempts at recording AV data have taken place, that at least one Extent on the disc will successfully certify. This Extent that has been successfully certified is then reserved for purposes of write recovery. During recording, if the writing of data to a different Extent fails, then the AV data that cannot be written in the failed Extent is re-written in the certified/reserved Extent. Due to the fact that reserved extent has already been certified is, it is extremely unlikely that there will be any problems with the certified extent. Therefore, recovery from the write error is possible in only a single re-write. The inventive re-write provides a recovery that is deterministic; therefore, it can effectively be used in real-time recording applications, without lost of information, and with a limited memory budget.

Referring to FIG. 1, which is a blocks diagram illustrating the data structures employed by the present invention, the system of the invention maintains several lists. Typically a File System maintains these lists, but other access mechanism will be apparent to those skilled in the art. The BD system utilise a File System. All application data (AV-data and AV-Meta data, including Table of Content mechanism are typically located in files.

A List of Free Disc Space List 11 is maintained on the disc 5 that contains a list of all areas on the disc 5 that have not been written to. A Defect List 13 is maintained that contains a list of all known defective areas. A List of Unallocated Extents 15 provides a list of all the extents that have not yet been written to. A List of Written Extents 17 provides a list of all the extents that have been written to. A List of Reserved Extents 19 contains a list of extents that have been certified by writing to and reading from depending on the capabilities of the system to detect ‘write-errors’ during writing, if not then the classical method of write & verify is used as being free of defects and are reserved as areas in which to perform the re-writing of data that were the initial write of that data was attempted in a defective extent.

The AV Content Buffer 12 receives AV content that is to be written to the disc 5. The AV Content Buffer will deliver the AV Content to control 14, which has access to each of the aforementioned lists 11, 13, 15 and 19. Control 14 will determine where on the disc 5 the AV Content is to be written by tracking the next logical area that is to be written as indicated in the List of Unallocated Extents 15. The control section knows the next extent to be written by reading a pointer that is used with List of Unallocated Extents 15.

If the writing of the AV Content fails due to a defect in the extent selected for writing by the List of Unallocated Extents 15, then the AV Content will be written in an extent selected from the List of reserved Extents 19. The List of reserved Extents employs a pointer to determine the extent that will be used for rewriting. Preferably, selection of the reserved extent is done via the ‘Sequential Loop Recording’ method. ‘Sequential Loop Recording’ refers to allocating the next Extent such that it has a start address that is higher than the preceding Extent's end-address, so at the logical Volume space (e.g end of disc) there is a wrap around. ‘Sequential Loop Recording’ results in a equal average number of overwrites over the disc. It will be understood by those skilled in the art that ‘Sequential Loop Recording’ is the preferred method of selecting a reserved extent but that other methodologies are also viable, Preferably, if an Extent from Reserved List must be selected, then ‘Sequential Loop Recording’ rule is first applied and secondly a rule that selects in accordance with ‘less jump distance’ is applied.

Referring to FIG. 2, illustrates a flowchart for an algorithm, generally referred to as routine 20, illustrating the preferred embodiment of the invention. Routine 20 begins before attempting to write any AV content on disc 10 at start 21 upon placement of disc 10, such as a Blu-ray disc, into the player/recorder 10. Allocate Extents in Free Disc Space 22 will search the list of Free Space on Disc 11 to retrieve a predetermined number of extents. Extents are reserved based on total capacity that is determination necessary by the system tasks in bytes for the reserved list. This capacity determination depends on the amount of the system can spend on certification. The certification time is limited in case where recording begins directly after disc insertion and, in that situation; the certification time is limited proportionally to available buffer capacity. The system must at least be able to absorb all the data to be written while certifying at least one Extent of minimum length. The more time is available to the system, the more Extents and/or larger Extent that can be reserved. It is envisioned that additional extents can be reserved via a background process.

It is envisioned by the Invention that the system allocate one or more extents that are unused as determined by the list of extents contained within Free Space on Disc 11, with each of the allocated extents having the minimum extent.

The invention is applicable for all kind of systems that have real-time constraints and allow fragmented data chunks (also called in BD terminology Extents. It should be noted that the description provided below is just one example embodiment for the invention.

The Minimum Extent Lengths (MEL) for BD V1.0 is value that depends on streaming-rate. For transport streams up to 24 Mbit/sec., the MEL is 12 Mbyte, which is determined as a number of Error Correction Code (ECC) blocks, this is code, and when defective to some degree it can recover fully the protected data. For BD, an ECC-block is defined in terms of Clusters, which are 64K bytes large (64 sectors with 1024 bytes per sector). The Minimum Extent length of 12 Mbyte equals 192 Clusters. For digital video streams that occur at 28.8 Mbit/sec., the MEL is 24 Mbyte, the 24 Mbyte is simply twice the 12 Mbyte amount ( 2*192*64*1024 bytes). An Extent is a number of ECC block/sector/cluster (192) that each have 64 k user data capacity. For digital video streams that occur at 28.8 Mbit/sec., the MEL is 24 Mbyte (2*192*64*1024).

For BD-RE V2.0 the Minimum Extent Length is recommended 48 Mbytes with no discontinuity and the MEL is 60 Mbyte with limited discontinuity. Here, discontinuity refers to one more sectors that belong to the extent but not to File Data. In the BD-RE 2.0 standard, the minimum extent length is recommended. Thus, if the actual extent length is less than the recommended minimum, the recording that takes place will still be done according to the BD-RE 2.0 standard, but seamless playback is not guaranteed. To guaranty seamless recording, extents must have a minimum length. The performance of the optical pickup used by the system will determine the minimum length. It should be noted that the BD_RE V2.0 standard is still in development and the minimum Extent lengths of 48M and 60M could be changed in future, and that the foregoing discussion is presented as an example of the current state of the art that can be used in implementing the invention as best known to the inventor.

The minimum extent size depends on drive performance. The main properties are access time (command to data) and the rate data comes from the disc. In BD standard V2.0 minimum extent length is a recommendation, which means any length is valid. But for real-time constraint they must have still (theoretically) a minimum length. This length is less than recommended one in the standard.

Certify Extents 24 will perform writes to the extents and verify the writes to the extents to certify these extents. A selective algorithm is employed to determine if an extent is error free. If the selective algorithm cannot guarantee that the complete extent is error-free, then Certify Extents 24 should certify that sector.

Defects 26 will detect those extents that do not correctly verify and a branch to Add Defects to Defect List 27 to place those defects into the Defect List 13, after which Allocates Extents in Free Disc Space 22 will again be performed. If Defects 26 determines that an extent is defect free, then operation branches to Add Extents to Reserved List 28 to place these defect free extents into the List of Reserved Extents 19. Once the predetermined number of extents are certified and placed into the List of Reserved Extents 19, writing of AV content to disc 5 can begin.

The Writing of AV Content begins with Allocate Extent in Free Disc Space 32 that retrieves the next (or first) extent from the list of Free Space on Disc 11. Add Extent to Unwritten List 34 then places the extent in the List of Unallocated Extents 15. Any Disc space (free or allocated) is expressed and recorded on disc in free or occupied logical addresses. Extents are allocated in these disc spaces, and also expressed in logical addresses. Extents have special real-time allocation rules. Extents are in fact specialised disc spaces.

Write Extent with AV Content 36 recording the data from the AV Content 12 Buffer into the extent. Write errors 40 will detect if the AV Content has been successfully recorded into the extent. Due to the real-time constraints AV data is, preferably, not verified after writing, preferably the writing process will rely on detection of unrecoverable read errors.

If the data is correctly written then the extent is added to the List of Written Extents 17 and More to Write 30 determines if the AV Content Buffer 12 contains more data to be written onto disc 5. If the AV Content does not record properly into the selected extent, then the Defect List 13 is updated by Add Defects to Defect List 42 to include that extent that failed to successfully record. Re-write AV Content in Reserved Extent 44 then accesses the next extent from the List of Reserved Extents 19 and records the AV Content data that failed to previously successfully record in the extent indicated by the List of Reserved Extents 19. Move reserved Extent to the Written Extent List 46 then removes the extent as an entry from the List of Reserved Extents 19 and adds the extent as an entry to the List of written Extents 17. The written extent is from the List of Reserved Extents 19. A determination is made if the AV Content Buffer 12 still has additional data to be written, then operation branches to Allocate Extent in Free Disc Space 32. If the AV Content Buffer 32 does not have any remain content data then the player/recorder goes into a state of ready 50.

The foregoing description discusses the preferred manner of writing to disc 5 as envisioned by the invention. Preferably, the above-discussed function blocks discussed in FIG. 2 are each files that will be called by the algorithm 20. As such, certain function blocks in FIG. 2 will have different reference numerals such as Allocate Extents in Free Disc Space 22 and will have different reference numerals such as Allocate 32 but preferably will be the same file called at different times by the algorithm 20 oft the invention. In this manner, the files required to run algorithm 20 can be optimized.

Algorithm 20 can be performed in a pipelined manner to allocate extents for writing as needed, with the lists being update while allocation and actual writing/verification operations are taking place. .

The foregoing description details the embodiments most preferred by the inventor. Variations of these embodiments will be readily apparent to those skilled in the art, therefore the scope of the invention should be measured by the appended claims.

1. A player/recorder for a storage media comprising:
a content buffer configured to receive data for the player/recorder;
a control unit operatively coupled to designate areas within the storage media in which to place data received by the content buffer; and
a routine controlled by the control unit, the routine implementing a series of lists, the series of lists including a free area list designating areas within the storage media that are not used, a defect list detailing areas of the storage media that are defective and a reserved area list designating areas of the storage media that are certified as being free of defects.

2. The player/recorder of claim 1, wherein the routine further implements with the series of lists a written area list designating areas within the storage media that have already been written to.

3. The player/recorder of claim 2, wherein the control unit updates the series of lists to reflect each write and rewrite action performed by the player/recorder on the storage media.

4. The player/recorder of claim 1, wherein the control unit allocates a write area on the storage media from the free area list to place data received by the content buffer, instructs the player/recorder to write data received by the content buffer in the write area, performs a verification that the write area correctly recorded the data received by the content buffer and instructs the player/recorder to rewrites data received by the content buffer with a rewrite area designated by the reserved list if the verification determines that the data received by the content buffer did not record correctly.

5. The player/recorder of claim I wherein the routine creates a separate file that contains audiovisual (AV) data received by the content buffer.

6. The player/recorder of claim 1 wherein each lists are recorded on the storage media.

7. The player/recorder of claim 1 wherein the control unit allocates an area from the free area list in which to place data received by the content buffer.

8. The player/recorder of claim 5 wherein the control unit writes data received by the content buffer into the allocated area.

9. The player/recorder of claim 7 wherein the control unit places an entry into the defect list for the allocated area if defects are found during writing.

10. The player/recorder of claim 8 wherein the control unit re-writes the data received by the content buffer into a reserved areas designated by the reserved areas list.

11. The player/recorder of claim 9 wherein the control unit determines if the content buffer contains more data to be written.

12. The player/recorder of claim 8 wherein the control unit places an entry into a write list for the allocated area if the allocated area has been correctly written to.

13. A method for recording on a storage media comprising the steps of:
creating a list of free areas on storage media;
allocating at least one area from the list of free areas;
certifying the at least one area to be a defective free area;
placing an entry to the defect free area into a reserved list;
writing a set of data to a write area on the storage media; and
rewriting the set of data in the defect free area if the step of writing indicates that the set of data did not record correctly during the step of writing and placing an entry to the write area in a defect list.

14. The method of claim 13 wherein the step of writing further comprises selecting the write area from an un-allocated list that contains areas of the storage media that has not yet been written to.

15. The method of claim 13 wherein the step of verifying further comprises placing an entry to the write area in a write list if the set of data has been correctly written into the write area.

16. The method of claim 13 wherein the step of certifying further comprises:
identifying if the at least one area is defective;
placing an entry for the at least one area into the defect list; and
returning to step for allocating.

17. The method of claim 13 further comprising the following steps being performed prior the step of writing:
allocating an additional area within the storage media; and
placing an entry for the additional area in an unallocated list that contains areas of the storage media that has not yet been allocated.

18. The method of claim 13 wherein the storage media is a Blu-ray disc and each of the areas are extents having a minimum length.

19. The method of claim 13 further comprising of determining if additional writing is necessary.
